(19) United States
(12) Patent Application Publication
(10) Pub. No.: US 2010/0166815 A1
(43) Pub. Date: Jul. 1, 2010

(54) Method for Preparation of a Nanocomposite Material by Vapour Phase Chemical Deposition

(76) Inventors: Sophie Mailley, Le Pin (FR); Laurent Bedel, Quaix En Chartreuse (FR); Fabrice Emieux, Voreppe (FR)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 12/670,239

(22) PCT Filed: Jul. 18, 2008
(86) PCT No.: PCT/FR08/01061

§ 371 Date: Feb. 23, 2010

(30) Foreign Application Priority Data
Jul. 23, 2007 (FR) 0705333

(51) Int. Cl. A01N 25/34; A01N 59/16; A01N 59/00; A01P 1/00; C23C 16/00; H05H 1/24; B32B 5/16

(52) U.S. Cl. 424/405; 424/617; 424/600; 427/248.1; 427/255.6; 427/569; 427/255.11; 427/255.22; 427/255.25; 428/323; 977/841

(57) ABSTRACT

The invention relates to a method for preparing a nanocomposite material by simultaneous vapour phase chemical deposition and vacuum injection of nanoparticles and to the materials and nanoparticles obtained thus and the application thereof.

The present invention relates to a method of preparing a nanocomposite involving, simultaneously, chemical vapor deposition and vacuum injection of nanoparticles, to the composites materials and nanoparticles obtained by implementing this method, and to the applications thereof.

The technical field of the invention may be defined in general as that of preparing a nanocomposite coating on the surface of a substrate or support, it being possible for said coating to consist of a continuous layer of said nanocomposite coating in the form of a film of variable thickness or a discontinuous dispersion of composite nanoparticles.

These composite materials and nanoparticles are generally applicable in the fields of microelectronics (conducting, insulating or semiconducting films), mechanical engineering (wear-resistant and corrosion-resistant coatings), optics (radiation sensors) and, above all, catalysis, especially for environmental protection.

It is known that the properties of a metal change when the particles have a size within the nanometer range: noble metals such as gold (Au), platinum (Pt) and iridium (Ir) become very reactive when they reach the nanoscale size. When they are applied to the surface of a substrate, these metals give it particular properties enabling them to be used for example as fuel cell electrodes, antibacterial surfaces and surfaces applied for the photocatalytic and catalytic generation of energy. Depositing these metals on the surface of a substrate also makes it conceivable to store hydrogen and to texture surfaces.

Several types of methods for covering the surface of a substrate of this type with metal particles have already been proposed, such as impregnation and electrodeposition, these being among the most established methods.

Among the most recent methods are in particular CVD (chemical vapor deposition) methods. These methods have many advantages over impregnation and electrodeposition or even over PVD (physical vapor deposition) technologies. This is because CVD methods are used to cover parts of variable and complex geometry, such as catalyst supports, for example foams, honeycombs, ceramics and zeolites, without it being necessary to work in the high vacuum range, namely from 100 to 500 Pa, thereby providing a method that can be easily carried out on an industrial scale when compared with for example the PVD method.

This CVD technique consists in bringing a volatile compound of the material (or precursor) into contact with the surface to be covered, in the presence of other gases or not. One or more chemical reactions then occur, giving at least one solid product on the substrate. The other reaction products must be gaseous so that they can be removed from the reactor. The reaction may be broken up into five phases:
transport of the one or more gaseous reactive species onto the substrate;
adsorption of these reactants on the surface;
reaction in the adsorbed phase and growth of the film;
desorption of the volatile by-products; and
transport and evacuation of the gaseous products.

In “conventional” or “thermal” CVD, the substrate temperature (600-1400° C.) supplies the activation energy necessary for the heterogeneous reaction resulting in the growth of the deposited material. However, these high temperatures are not always compatible with the nature of the substrates to be covered.

To reduce the formation temperature, various alternative ways have been developed that involve the use of more reactive precursors, such as organometallics (or OMCVD, i.e. organometallic chemical vapor deposition) that react at low temperatures (200-600° C.). The use of a more reactive precursor involves using one or more compounds having low-energy bonds that break at low temperature. The compounds most often used are therefore organometallics that include, most of the time in their structure, the element or elements to be deposited. In the OMCVD method, a chamber under a controlled atmosphere is used, into which the gaseous precursors are injected, such as titanium tetraisopropoxide with O₂ for example if titanium dioxide is to be deposited. The substrate is heated and the chemical deposition reaction takes place on the surface after the gaseous reactants have been adsorbed. The deposited film can be created only under thermodynamic conditions that allow the reaction to take place: the energy necessary for the reaction is provided in thermal form by heating either the entire chamber (hot-wall furnace) or only the substrate carrier (cold-wall furnace).

Thanks to this OMCVD method, it is also possible to form composite films, for example based on silver and titanium oxide (TiO₂) on the surface of a substrate, as described in particular in international application WO 2007/000556. Specifically, OMCVD methods also allow nanocomposite films of oxides and metal nanoparticles to be formed by simultaneously injecting two precursors (silver pivalate and titanium tetraisopropoxide for example). In this case also, it is necessary to use each of the components in the form of liquid precursors or of a solution of precursors in suitable solvents, such as mesitylene and xylene, optionally in the presence of an amine and/or of a nitrile so as to improve the dissolution of said precursor in the solvent.

However, the preparation of certain composites is not possible according to the method of preparing composite films described in the above international application insofar as the two liquid precursors and the reactive gases introduced into the CVD reactor interact to form a single compound: it has never been possible to obtain two distinct products coming from each of the precursors. For example, it is impossible to obtain an oxide matrix with nitride nanoparticles from an oxide precursor and a nitride precursor.

It is to remedy these limiting constraints on preparing composites by OMCVD methods that the inventors have developed what forms the subject matter of the present invention.

The inventors thus set themselves the objective of providing a novel OMCVD method for obtaining any type of nanocomposite without it being necessary to have each of the precursors in liquid form or dissolved in a suitable solvent.

One subject of the present invention is therefore a method of forming a nanocomposite, consisting of at least two elements, on the surface of a substrate, said method comprising at least one chemical vapor deposition step in the presence of a gas, characterized in that said step is carried out by simultaneous direct liquid injection:
a) of at least one injection liquid I₁ consisting of:
   i) at least one liquid precursor of one of said elements or
   ii) a solution of at least one precursor of one of said elements in an organic solvent; and
b) of solid nanoparticles of the other element, said nanoparticles being present in the form of a homogeneous dispersion within the injection liquid I₁ and/or within an injection liquid I₂ separate from the injection liquid I₁.

Within the context of the present invention, the word “nanocomposite” is used to denote a material comprising at least two distinct physical phases consisting either of a juxtaposition of nanoparticles of one of the two elements and nanoparticles of the other element, or a matrix of one of the two elements containing one or more types of nanoparticles of the other element.

The method according to the present invention thus makes it possible to obtain nanocomposites that cannot be obtained by CVD methods of coating formation. It thus becomes possible using the method forming the subject matter of the present invention to produce predefined nanocomposite structures integrating, on the one hand, a metal or ceramic (oxide) phase generated by the CVD method and solid nanoparticles introduced via the injection device.

The liquid precursors or precursors dissolved in an organic solvent (injection liquid I₁ may be chosen from organometallic precursors and metal salts. Advantageously, the latter are chosen from chlorinated metal salts and ammonium metal salts.

According to one advantageous embodiment of the invention, the organometallic precursors are chosen from metal dialkyls, metal β-diketonates, precursors with carbonyl or phosphine ligands or with chlorinated ligands, n-cyclopentadienyl metal complexes, cyclooctadienyl metal complexes and precursors with an olefin or allyl group, said metals preferably being chosen from the metals of the first three rows of columns IVB to IB of the Periodic Table, Li, Si, Ge and alloys thereof.

Among these organometallic precursors, mention may in particular be made of titanium tetraisopropoxide and platinum acetylacetate.

The organic solvent for the injection liquid I₁ is generally chosen from solvents having an evaporation temperature below the decomposition temperature of the precursor(s). The organic solvent is preferably chosen from liquid organic compounds having an evaporation temperature between approximately 50 and 200° C. inclusive under normal pressure conditions. Among such organic compounds, mention may in particular be made of mesitylene, cyclohexane, xylene, toluene, n-octane, acetylacetone, ethanol and mixtures thereof.

The injection liquid I₁ may further comprise an amine and/or a nitrile and/or water so as to make it easier to dissolve the precursor or precursors that are present therein. This is particularly valid when the precursor used is a silver precursor.

In this case, the total amount of amine and/or nitrile and/or water in the injection liquid I₁ is generally greater than 0.1% by volume and preferably this amine and/or nitrile and/or water concentration is less than 20% by volume.

The amine optionally present in the injection liquid I₁ is generally chosen from primary, secondary or tertiary monoamines such as, for example, n-hexylamine, isobutylamine, di-sec-butylamine, triethylamine, benzylamine, ethanolamine, diisopropylamine, polyamines and mixtures thereof.

The nitrile optionally present in the injection liquid I₁ is generally chosen from acetonitrile, valeronitrile, benzonitrile, propionitrile and mixtures thereof.

Preferably, the solid nanoparticles present in the form of a dispersion within the injection liquids I₁ and/or I₂ are chosen from mineral nanoparticles, such as, for example, silica oxide (SiO₂), titanium oxide (TiO₂), zirconium oxide (ZrO₂) and cerium oxide (CeO₂) nanoparticles. In another advantageous embodiment of the method according to the invention, the nanoparticles are carbides or nitrides.

Of course, a person skilled in the art will take measures to ensure that the size of the nanoparticles or of their aggregates remains compatible with the diameter of the injectors so as to avoid any risk of the latter becoming blocked.

To improve the homogeneity of the dispersion of nanoparticles within the injection liquids I₁ and/or I₂, it is possible to apply an ultrasound treatment.

The injection liquid I₂ optionally used in the method according to the present invention also consists of an organic solvent in which the nanoparticles are of course not soluble.

This organic solvent may for example be chosen from the solvents mentioned above for the injection liquid I₁.

Of course, when the method according to the invention employs an injection liquid I₁ and an injection liquid I₂, then the solvents constituting these injection liquids may be identical or different.

When implementing the method according to the invention, the injection liquid or liquids (I₁ and I₂) are introduced into a vaporization device via which they are sent into a heated deposition chamber that contains the substrate, at least one surface of which has to be coated with the nanocomposite.

In the method according to the present invention, the deposition is generally carried out at a low temperature, i.e. at a substrate temperature not exceeding 500° C., this temperature being of course adjusted according to the nature of the substrate and to the materials used.

This is an additional advantage of the method according to the invention, whereby it remains possible to work at a low temperature compatible with a large number of substrates.

The deposition may be carried out at atmospheric pressure but it is preferably carried out under a vacuum, for example with a pressure of 40 to 1000 Pa.

The deposition time is generally 2 to 90 minutes.

The deposition may advantageously be carried out with plasma assistance, such as with a low-frequency (LF), radiofrequency (RF) or pulsed DC plasma.

The substrate on which the deposition is carried out may be a porous substrate or a dense substrate. These substrates are as diverse as glass, silicon, metals, steels, ceramics, such as alumina, ceria and zirconia, fabrics, zeolites, polymers, etc.

The gas in the presence of which the deposition is carried out is generally composed of a reactive gas and/or a vapor-carrying inert gas.

The reactive gas may be chosen from oxygen, hydrogen, ammonia, nitrous oxide, carbon dioxide, oxone, nitrogen dioxide and mixtures thereof.

The vapor-carrying inert gas may be chosen from argon, nitrogen, helium and mixtures thereof.

The films deposited may take various forms depending on the mode of nucleation and growth of each of the elements involved.

Another subject of the invention is therefore the supported nanocomposite that can be obtained by implementing the method according to the invention, and as defined above, characterized in that it consists of:
i) either a continuous layer consisting of a metal, oxide, carbide or nitride matrix having inclusions of at least one family of nanoparticles chosen from metal nanoparticles, oxide nanoparticles, carbide nanoparticles and nitride nanoparticles;
ii) or a discontinuous dispersion of nanoparticles, said dispersion being in the form of a juxtaposition of at least two families of nanoparticles chosen from metal nanoparticles, oxide nanoparticles, carbide nanoparticles and nitride nanoparticles.

According to one advantageous embodiment of the invention, the nanocomposite consists of:
i) a continuous oxide matrix having inclusions of at least one family of nanoparticles chosen from metal nanoparticles, carbide nanoparticles, nitride nanoparticles and oxide nanoparticles, the oxide of the latter being different from the oxide from which the continuous matrix is formed;
ii) a continuous matrix of a metal or a metal alloy having inclusions of at least one family of nanoparticles chosen from carbide nanoparticles, nitride nanoparticles, oxide nanoparticles and nanoparticles of a metal (or a metal alloy) of different nature from that of the metal or the metal alloy from which the continuous matrix is formed;
iii) a continuous matrix of a nitride having inclusions of at least one family of nanoparticles chosen from metal nanoparticles, carbide nanoparticles, oxide nanoparticles and nanoparticles of a nitride of different nature from the nitride from which the continuous matrix is formed; and
iv) a continuous matrix of a carbide having inclusions of at least one family of nanoparticles chosen from metal nanoparticles, oxide nanoparticles, nitride nanoparticles and nanoparticles of a carbide of different nature from the carbide from which the continuous matrix is formed.

Advantageously, the nanocomposite comprises at least one oxide and at least one metal, it being possible for example for these two elements to be indifferently and respectively present according to any one of the above configurations i) and ii).

Within the nanocomposite according to the invention (after deposition), the size of the nanoparticles (in inclusion form or dispersion form) is by definition less than 100 nm.

Generally, the continuous matrix has a thickness of 50 nm to 2 μm.

By dint of the chemical nature of the deposited nanoparticles (of the mineral, carbide or nitride type) and the morphology of the deposited films (large number of active nanoscale sites very well dispersed over the surface of the substrate), the layers involved may have a wide variety of applications.

Another subject of the present invention is therefore the use of a nanocomposite as defined above, based on silver and titanium, as an antibacterial coating.

When the nanocomposite is a nanocomposite based on platinum and mineral nanoparticles such as SiO₂, TiO₂, ZrO₂ or CeO₂ nanoparticles, it has an enhanced electrocatalytic activity and may be used for fuel cells.

Thanks to the method according to the invention to the invention, it thus becomes possible to obtain coatings advantageously having a lower content of noble metals, generally between 0.01 and 0.5 mg/cm² and more particularly of the order of about 0.05 mg/cm².

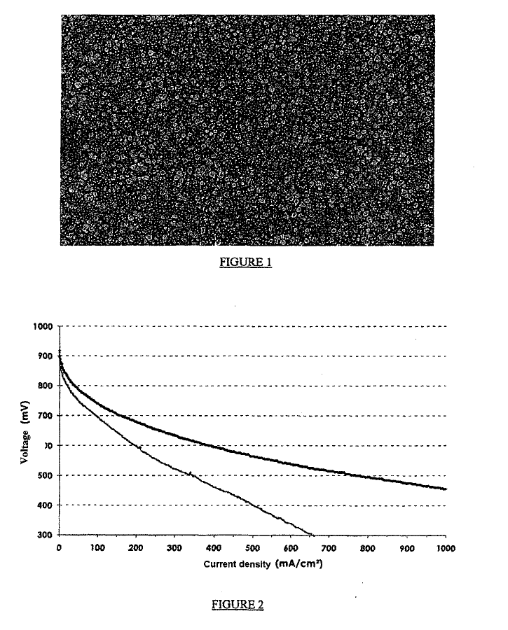

Apart from the above arrangements, the invention also includes other arrangements that will emerge from the following description, referring to examples of supported nanocomposites prepared using the method according to the invention, and to the appended FIGS. 1 to 3 in which:

FIG. 1 is a micrograph obtained by scanning electron microscopy (SEM) with a magnification of ×10⁵, of a nanocomposite consisting of platinum and silica nanoparticles present on the surface of a planar silicon substrate;

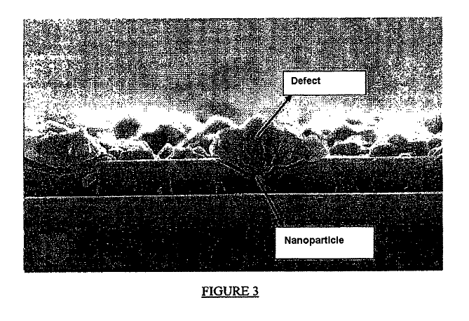

FIG. 2 shows the polarization curves for a fuel cell involving a nanocomposite consisting of platinum and silica nanoparticles. In this figure, the voltage (E) expressed in mV across the terminals is plotted as a function of the current density (i) expressed in mA/cm², the upper curve corresponding to operation in hydrogen and oxygen (80/45/O₂, 100% relative humidity), while the lower curve corresponding to operation in hydrogen and air (80/45/air, 100% relative humidity); and

FIG. 3 is a micrograph obtained by scanning electron microscopy (SEM), with a magnification of ×10⁵, in cross section, of a nanocomposite consisting of a continuous TiO₂ matrix having SiO₂ nanoparticle inclusions present on the surface of a planar silicon substrate.

However, it should be understood that these examples have been given merely as purely illustrative examples of the invention, which in no way constitute any limitation thereof.

### EXAMPLES

In the illustrative examples that will be described below, the films were deposited using a vaporization device sold under the brand name Inject®, “Système d′injection et d′évaporation de précurseurs liquides purs ou sous forme de solutions [System for injecting and evaporating liquid precursors either in pure form or in the form of solutions]”, by the company Jipelec, coupled with a chemical vapor deposition chamber containing the substrate to be coated. Such a vaporization device has been described in Chem. Mat., 2001, 13, 3993.

The Inject® device comprises four main parts:
i) the container(s) for storing the chemical solution(s) of precursors, with or without the nanoparticles;
ii) one or more injectors, for example of the gasoline engine injector type, connected to the container(s) for storing the chemical solution(s) of precursors via one or more feed lines or pipes, said injector(s) being controlled by an electronic control device;
iii) a feed line or pipe for the inert carrier gas, such as for example argon; and
iv) a vaporization device (evaporator).

The deposition chamber, that contains the substrate to be coated, includes heating means, a reactive gas (for example oxygen) or inert gas supply, and pumping and pressure regulation means.

The chamber and the substrate to be coated are maintained at a temperature above that of the evaporator so as to create a positive thermal gradient. The chemical solution of metal precursor is introduced into the container maintained under pressure (0.2 or 0.3 MPa for example) and then sent from the container, via the injector(s), (through the pressure difference), into the evaporator which is maintained at a lower pressure. The injection flow rate is controlled by varying the frequency and the duration of opening the injector(s), which may be considered as a micro solenoid valve and which is controlled by a computer.

### Example 1

### Preparation of a Nanocomposite as Fuel Cell Electrodes

The objective of this example is to demonstrate that the method according to the present invention can be used to prepare fuel cell electrode materials having two types of component families having a catalytic function.

In this example, platinum nanoparticles and silica nanoparticles were deposited on a diffusion layer substrate formed by carbon electrodes of the ELAT® type (E-tek product sold by the company De Nora) and on a silicon substrate.

A chemical deposition solution was prepared comprising, on the one hand, the organometallic precursor, namely platinum acetylacetonate, dissolved in the form of (Pt(Δc)₂) complexes with a concentration of 0.03 mol/l in toluene and, on the other hand, SiO₂ nanoparticles of nanoparticulate size of less than 100 nm, in an amount of 15% by weight.

The temperatures of the evaporator and the substrate were fixed at 220° C. and 320° C. respectively. The other operating conditions are summarized below:
injector frequency: 3 Hz;
injector open time: 2 ms;
N₂/O₂ flow rate: 60-240 ml;
pressure: 800 Pa;
deposition time: 20 min.

The appended FIG. 1 shows a scanning electron micrograph of the surface of the substrate after deposition (with ×10⁵ magnification). In this figure, the silicon substrate appears dark gray, the SiO₂ nanoparticle agglomerates corresponding to the coarse light gray grains and the platinum nanoparticles to the small light gray grains. This figure therefore shows that, in the case of deposition on a diffusion layer, the SiO₂ nanoparticles are nanodispersed over the surface of the substrate and may have, in their vicinity or on the surface of themselves, catalytic platinum nanoparticles.

This coating produced on a diffusion layer constitutes an electrode of a fuel cell or of an electrolyser.

The polarization curves for this fuel cell are shown in appended FIG. 2. In this figure, the voltage (E) expressed in mV across the terminals is plotted as a function of the current density (i) expressed in mA/cm². In this figure, the upper curve corresponds to operation in hydrogen and oxygen (80/45/O₂, 100% relative humidity), while the lower curve corresponds to operation in hydrogen and air (80/45/air, 100% relative humidity).

It may be seen that the electrode thus produced, involving a very small loading of platinum (0.05 mg/cm²), operates well. These results indicate greater dispersion of the active noble catalyst and good catalytic kinetics despite a small amount of platinum present.

According to this same method, it is possible to prepare this type of electrode using different mineral nanoparticles such as, for example, TiO₂, ZrO₂ or CeO₂ nanoparticles, for electrolyser applications favoring catalysis.

### Example 2

### Surface Texturizing

The method described above in example 1 was also repeated on silicon using a chemical deposition solution comprising, as organometallic precursor, titanium tetraisopropoxide (TTIP) with a concentration of 1 mol/l in xylene and, on the other hand, SiO₂ nanoparticles of 50 nm nanoparticulate size, in an amount of 15% by weight. The deposition conditions used were the following:
evaporator temperature: 200° C.;
injector frequency: 2 Hz;
injector open time: 2 ms;
N₂/O₂ flow rate: 40-160 ml;
pressure: 800 Pa;
deposition time: 7 min.

The appended FIG. 3 shows a scanning electron micrograph of a section through the substrate after deposition (×10⁵ magnification). By examining this figure, it is possible to observe that the fact of inserting silica nanoparticles during the growth of the TiO₂ film makes it possible to generate surface defects resulting in uniform texturization thereof. This growth of defects from the nanoparticles uniformly distributed over the surface of the substrate gives a uniform structuring of the surface with defects having a size of between 50 nm and 1 μm and a distance separating them of 10 to 5 μm depending on the density of the nanoparticles injected during the deposition step. This surface texturization has the effect of increasing the active surface area, which may be advantageous in particular for photocatalysis applications.

1. A method of forming a nanocomposite, consisting of at least two elements, on the surface of a substrate, said method comprising at least one chemical vapor deposition step in the presence of a gas, characterized in that said step is carried out by simultaneous direct liquid injection:
a) of at least one injection liquid I₁ consisting of:
i) at least one liquid precursor of one of said elements or
ii) a solution of at least one precursor of one of said elements in an organic solvent; and
b) of solid nanoparticles of the other element, said nanoparticles being present in the form of a homogeneous dispersion within the injection liquid I₁ and/or within an injection liquid I₂ separate from the injection liquid I₁.

2. The method as claimed in claim 1, characterized in that the liquid precursors or precursors dissolved in an organic solvent are selected from the group consisting of organometallic precursors and metal salts.

3. The method as claimed in claim 2, characterized in that said metal salts are selected from the group consisting of chlorinated metal salts and ammonium metal salts.

4. The method as claimed in claim 2, characterized in that the organometallic precursors are selected from the group consisting of metal dialkyls, metal β-diketonates, precursors with carbonyl or phosphine ligands or with chlorinated ligands, n-cyclopentadienyl metal complexes, cyclooctadienyl metal complexes and precursors with an olefin or allyl group.

5. The method as claimed in claim 4, characterized in that said metals are chosen from the metals of the first three rows of columns IVB to IB of the Periodic Table, Li, Si, Ge and alloys thereof.

6. The method as claimed in claim 1, characterized in that the organometallic precursors are selected from the group consisting of titanium tetraisopropoxide and platinum acetylacetate.

7. The method as claimed in claim 1, characterized in that the organic solvent for the injection liquid I₁ comprises a solvent having an evaporation temperature below the decomposition temperature of the precursor(s).

8. The method as claimed in claim 7, characterized in that said solvent comprises a liquid organic compounds having an evaporation temperature between 50 and 200° C. inclusive under normal pressure conditions.

9. The method as claimed in claim 7, characterized in that said solvent is selected from the group consisting of mesitylene, cyclohexane, xylene, toluene, n-octane, acetylacetone, ethanol and mixtures thereof.

10. The method as claimed claim 1, characterized in that the injection liquid I₁ further comprises an amine and/or a nitrile and/or water.

11. The method as claimed in claim 10, characterized in that the total amount of amine and/or nitrile and/or water in the injection liquid I₁ is less than 20% by volume.

12. The method as claimed in claim 10, characterized in that the amine is selected from the group consisting of from n-hexylamine, isobutylamine, di-sec-butylamine, triethylamine, benzylamine, ethanolamine, diisopropylamine, polyamines and mixtures thereof.

13. The method as claimed in claim 10, characterized in that the nitrile is selected from the group consisting of from acetonitrile, valeronitrile, benzonitrile, propionitrile and mixtures thereof.

14. The method as claimed in claim 1, characterized in that the solid nanoparticles present in the form of a dispersion within the injection liquids I₁ and/or I₂ are chosen from mineral nanoparticles.

15. The method as claimed in claim 14, characterized in that the mineral nanoparticles are selected from the group consisting of from silica oxide, titanium oxide, zirconium oxide and cerium oxide nanoparticles.

16. The method as claimed in claim 1, characterized in that the nanoparticles are carbides or nitrides.

17. The method as claimed in claim 1 characterized in that the injection liquid I₂ comprises a solvent having an evaporation temperature below the decomposition temperature of the precursor(s).

18. The method as claimed in claim 1, characterized in that the injection liquid or liquids (I₁ and I₂) are introduced into a vaporization device via which they are sent into a heated deposition chamber that contains the substrate, at least one surface of which has to be coated with said nanocomposite.

19. The method as claimed in claim 1, characterized in that the deposition is carried out at a substrate temperature not exceeding 500° C.

20. The method as claimed in claim 1, characterized in that the deposition is carried out at atmospheric pressure or under a vacuum with a pressure of 40 to 1000 Pa.

21. The method as claimed in claim 1, characterized in that it is carried out with plasma assistance.

22. The method as claimed in claim 1, characterized in that the substrate is dense or porous and is selected from the group consisting of from glass, silicon, metals, steels, ceramics, fabrics, zeolites and polymers.

23. The method as claimed in claim 1, characterized in that the gas is composed of a reactive gas and/or a vapor-carrying inert gas.

24. The method as claimed in claim 23, characterized in that the reactive gas is selected from the group consisting of from oxygen, hydrogen, ammonia, nitrous oxide, carbon dioxide, oxone, nitrogen dioxide and mixtures thereof.

25. The method as claimed in claim 23, characterized in that the vapor-carrying inert gas is selected from the group consisting of from argon, nitrogen, helium and mixtures thereof.

26. A supported nanocomposite that can be obtained by implementing the method as defined in claim 1, characterized in that it consists of:
i) either a continuous layer consisting of a metal, oxide, carbide or nitride matrix having inclusions of at least one family of nanoparticles selected from the group consisting of from metal nanoparticles, oxide nanoparticles, carbide nanoparticles and nitride nanoparticles;
ii) or a discontinuous dispersion of nanoparticles, said dispersion being in the form of a juxtaposition of at least two families of nanoparticles selected from the group consisting of from metal nanoparticles, oxide nanoparticles, carbide nanoparticles and nitride nanoparticles.

27. The composite as claimed in claim 26, characterized in that it consists of:
i) a continuous oxide matrix having inclusions of at least one family of nanoparticles selected from the group consisting of from metal nanoparticles, carbide nanoparticles, nitride nanoparticles and oxide nanoparticles, the oxide of the latter being different from the oxide from which the continuous matrix is formed;
ii) a continuous matrix of a metal or a metal alloy having inclusions of at least one family of nanoparticles selected from the group consisting of from carbide nanoparticles, nitride nanoparticles, oxide nanoparticles and nanoparticles of a metal (or a metal alloy) of different nature from that of the metal or the metal alloy from which the continuous matrix is formed;
iii) a continuous matrix of a nitride having inclusions of at least one family of nanoparticles selected from the group consisting of from metal nanoparticles, carbide nanoparticles, oxide nanoparticles and nanoparticles of a nitride of different nature from the nitride from which the continuous matrix is formed; and
iv) a continuous matrix of a carbide having inclusions of at least one family of nanoparticles selected from the group consisting of from metal nanoparticles, oxide nanoparticles, nitride nanoparticles and nanoparticles of a carbide of different nature from the carbide from which the continuous matrix is formed.

28. The composite as claimed in claim 26, characterized in that it comprises at least one oxide and at least one metal.

29. The use of a nanocomposite as defined in claim 26, based on silver and titanium, as an antibacterial coating.

30. The use of a nanocomposite as defined in claim 26, based on platinum and mineral nanoparticles, as an electrocatalyst.
